(19) United States
(12) Patent Application Publication
(10) Pub. No.: US 2015/0173231 A1
(43) Pub. Date: Jun. 18, 2015

(54) TRAY ASSEMBLY FOR A RACK MOUNT TYPE STORAGE UNIT

(71) Applicant: Sanmina Corporation, San Jose, CA (US)

(72) Inventors: Peter RADO, Los Altos, CA (US); David BAKER, Jamestown, RI (US); Dimitry Struve, Santa Cruz, CA (US); Richard BENNETT, Colorado Springs, CA (US)

(21) Appl. No.: 14/569,487

(22) Filed: Dec. 12, 2014

Related U.S. Application Data
(60) Provisional application No. 61/915,699, filed on Dec. 13, 2013.

(51) Int. Cl. H05K 7/02; H05K 7/14; H05K 7/18

(52) U.S. Cl. CPC H05K 7/02; H05K 7/18; H05K 7/1491; H05K 7/1492

(57) ABSTRACT

A novel tray assembly for a rack mount type storage unit is provided. The tray assembly is adapted to receive an enclosure. When within the tray assembly, the enclosure may be located within a first position, a second position or a third position. When in the first position, the enclosure is fully received within the tray assembly and the tray assembly is fully received within the rack and is operational. When in the second position, the tray assembly is fully received within the rack and the enclosure is partially slid out of the tray assembly and rack for maintenance, repair, etc. while the enclosure is still powered and running. When in the third position, the enclosure is fully received within the tray assembly for easy insertion into or removal from a rack.

### CLAIM OF PRIORITY

The present application for patent claims priority to U.S. Provisional Application No. 61/915,699 entitled “Tray Assembly for a Rack Mount Type Storage Unit”, filed Dec. 13, 2013, which is hereby expressly incorporated by reference.

### FIELD

Various features relate to improvements to enclosures mounted in a rack mount type storage unit.

### BACKGROUND

Rack-mounted describes a unit of electronic equipment that is housed in a metal framework called an equipment rack. Usually an equipment rack contains multiple “bays”, each designed to hold enclosures containing a unit of equipment such as a computer server. Typically, the equipment unit is mounted (inserted into a bay in the rack) and secured in place with screws.

When enclosures are mounted into the rack, the enclosures receive power by plugging into common bus bars that are part of the rack. The enclosures, slid into rack location supported brackets installed into the rack, have a connector at the rear plugging into the bus bar. These enclosures are serviced in this static position until needing to be completely removed from the rack. As enclosures must be unplugged from the bus bar prior to removal or even partially slid out of the rack, the enclosure cannot be serviced while still powered and running within the rack. In higher complexity systems, however, there is a need for servicing enclosures while partially slid out of the rack while still powered and running.

In view of the above, there is a need for a tray assembly that allows for an enclosure to be slid out of the rack while still allowing the bus bar connector and power cables to remain plugged into the enclosure. Additionally, there is a need for enclosures that can be partially slid out of the rack to also have the ability to be completely removed from the rack disconnecting the connector from the bus bar while maintaining the bus bar in the rack.

### SUMMARY

The following presents a simplified summary of one or more implementations in order to provide a basic understanding of some implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

According to one feature, a tray assembly for a rack mount storage unit is provided. The tray assembly includes a back rail having a bus bar connector; a pair of side rails, the back rail located between and integrally connected to the pair of side rails; a pair of slide rails mounted to the pair of side rails and adapted to receive an enclosure, the pair of slide rails allowing the enclosure to be slid into and partially out of the tray assembly; a pair of inward spring loaded side locks integrally connected to and extending outwardly from the pair of side rails; a bus bar connector located in the back rail; and a power cable management system, operable between a first position and a second position, located in an interior space of the housing and adapted for receiving power cables, wherein a first end of the power cable management system is pivotably secured to the back rail and a second end of the power cable management system moves within the interior space of the housing in direct relation to the movement of the enclosure.

According to one aspect, the power cable management system includes a first arm member; a second arm member; and a center arm member, the center arm member pivotably secured between the first arm member and the second arm member. The first and second arm members may be U-shaped and adapted to receive the power cables.

According to another aspect, the tray assembly further includes a pair of hooks extending perpendicularly outward from the pair of inward spring loaded side locks adapted to be received within holes in the rack mount storage unit.

According to yet another aspect, when the power cable management system is in the first position, the first arm member and second arm member are located substantially parallel to each other.

According to yet another aspect, when the power cable management system is in the second position, the first arm member and the second arm member have a generally triangular configuration.

According to yet another aspect, the power cable management system moves between the first position and the second position when the enclosure is being slid into or at least partially out of the tray assembly.

According to yet another aspect, the pair of slide rails allows the enclosure to slide partially outwards from the tray assembly when the tray assembly is installed in the rack mount storage unit.

According to yet another aspect, the enclosure includes a pair of retaining clips located on opposite sides of the enclosure and adapted to clip onto the pair of inward spring loaded side locks securing the enclosure entirely within the tray assembly.

According to yet another aspect, a first end of the power cables is secured to a power connector located on a back end of the enclosure.

According to yet another aspect, a second end of the power cables is secured to the bus bar connector located on the back rail of the tray assembly.

According to another feature, a tray assembly for a rack mount storage unit is provided. The tray assembly includes a back rail having a bus bar connector; a pair of side rails, the back rail located between and integrally connected to the pair of side rails; a pair of slide rails mounted to the pair of side rails and adapted to receive an enclosure, the pair of slide rails allowing the enclosure to be slid into and partially out of the tray assembly; a pair of inward spring loaded side locks integrally connected to and extending outwardly from the pair of side rails; a bus bar connector located in the back rail; and a power cable management system, operable between a first position and a second position, located in an interior space of the housing and adapted for receiving power cables, wherein a first end of the power cable management system is pivotably secured to the back rail and a second end of the power cable management system moves within the interior space of the housing in direct relation to the movement of the enclosure; wherein the power cable management system moves between the first position and the second position when the enclosure is being slid into or at least partially out of the tray assembly.

According to another aspect, the power cable management system comprises a first arm member; a second arm member having a U-shape and adapted to receive the power cables; and a center arm member having a U-shape and adapted to receive the power cables, the center arm member pivotably secured between the first arm member and the second arm member.

According to yet another aspect, the tray assembly further includes a pair of hooks extending perpendicularly outward from the pair of inward spring loaded side locks adapted to be received within holes in the rack mount storage unit.

According to yet another aspect, when the power cable management system is in the first position, the first arm member and second arm member are located substantially parallel to each other.

According to yet another aspect, when the power cable management system is in the second position, the first arm member and the second arm member have a generally triangular configuration.

According to yet another aspect, the power cable management system moves between the first position and the second position when the enclosure is being slid into or at least partially out of the tray assembly.

According to yet another aspect, the pair of slide rails allows the enclosure to slide partially outwards from the tray assembly when the tray assembly is installed in the rack mount storage unit.

According to yet another aspect, the enclosure includes a pair of retaining clips located on opposite sides of the enclosure and adapted to clip onto the pair of inward spring loaded side locks securing the enclosure entirely within the tray assembly

### BRIEF DESCRIPTION OF THE DRAWINGS

FIG. 1 illustrates a tray assembly or outer shell, according to one aspect.

FIG. 2 illustrates the tray assembly of FIG. 1 having an enclosure partially slid outwards in a second position.

FIG. 3 illustrates a close up view of a spring loaded side lock of the tray assembly of FIG. 1 compressed and retained by a retaining clip.

FIG. 4 illustrates a close up view of a spring loaded side lock of the tray assembly of FIG. 1 released and sprung out from retaining clip.

FIG. 5 illustrates a pair of hooks on the spring loaded side lock for automatically engaging with and latching into hold on a rack.

FIG. 6 illustrates a bus bar connector extending outwardly from a back rail of the tray assembly of FIG. 1.

FIG. 7 illustrates a gap formed between the rear of an enclosure and its stop in the tray assembly as the enclosure is slid into tray assembly.

FIG. 8 illustrates the tray assembly of FIG. 1 installed in a rack.

### DETAILED DESCRIPTION OF THE INVENTION

In the following detailed description of the invention, numerous specific details are set forth in order to provide a thorough understanding of the invention. However, the invention may be practiced without these specific details. In other instances, well known methods, procedures, and/or components have not been described in detail so as not to unnecessarily obscure aspects of the invention.

In the following description, certain terminology is used to describe certain features of one or more embodiments. The term “rack” may refer to any type of frame-like structure adapted to hold and display equipment. The term “enclosure” may refer to chassis for storing data storage drives, hereinafter referred to as “drives”, mounted or inserted into a rack mount type storage unit. The term “data storage drive” may refer to a hard disk drive (HDD), a solid state drive or any type of drive for storing data. The drives may be top mounted or may be side mounted as described in U.S. patent application Ser. No. 13/782,911 which is assigned to the assignee hereof and hereby expressly incorporated by reference herein.

The term “hole” may refer to any opening through a structure and/or component or a hollowed-out place in a structure and/or component, including apertures, bores, cavities, chambers, grooves, notches, passages, slits and slots.

### OVERVIEW

Provided herein is a novel tray assembly for a rack mount type storage unit. The tray assembly is adapted to receive an enclosure. When within the tray assembly, the enclosure may be located within a first position, a second position or a third position. When in the first position, the enclosure is fully received within the tray assembly and the tray assembly is fully received within the rack and is operational. When in the second position, the tray assembly is fully received within the rack and the enclosure is partially slid out of the tray assembly and rack for maintenance, repair, etc. while the enclosure is still powered and running. When in the third position, the enclosure is fully received within the tray assembly for easy insertion into or removal from a rack.

### Tray Assembly

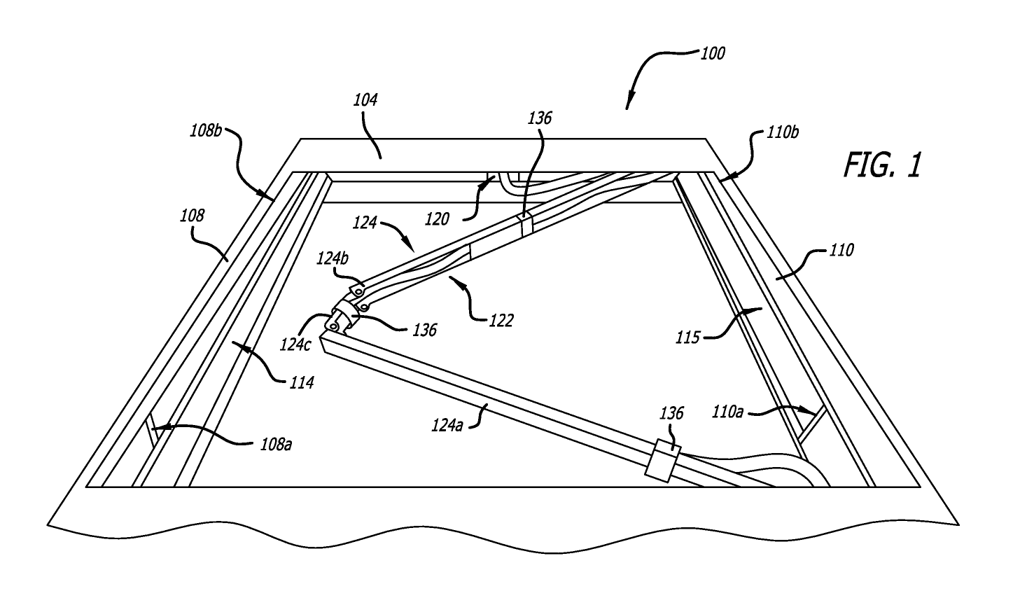

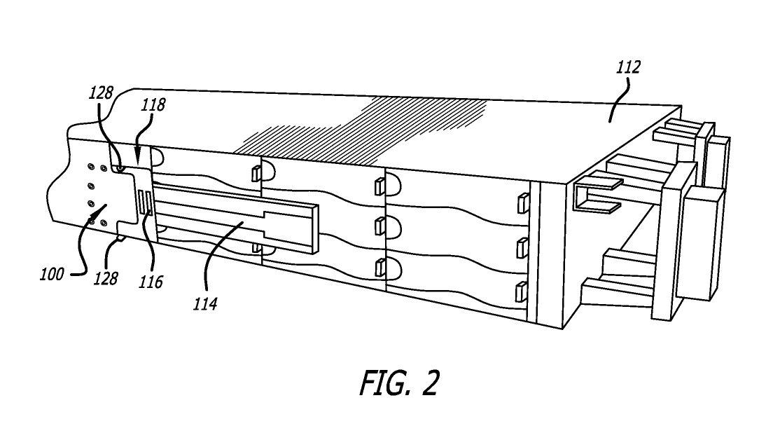

FIG. 1 illustrates a tray assembly or outer shell 100, according to one aspect. The tray assembly 100 may be placed on supporting “L” brackets located within the rack, although other types of brackets may be utilized. As shown, the tray assembly 100 may include a back rail 104 integrally connected to first and second side rails 108, 110. The tray assembly 100 may be adapted or sized to receive an enclosure 112 (See FIG. 2).

The first side rail 108 may have a first side rail top end 108a and a first side rail bottom end 108b while the second side rail may have a second side rail top end 110a and a second side rail bottom end 110b. The back rail 104 may be connected between the first side rail bottom end 108b and the second side rail bottom end 110b.

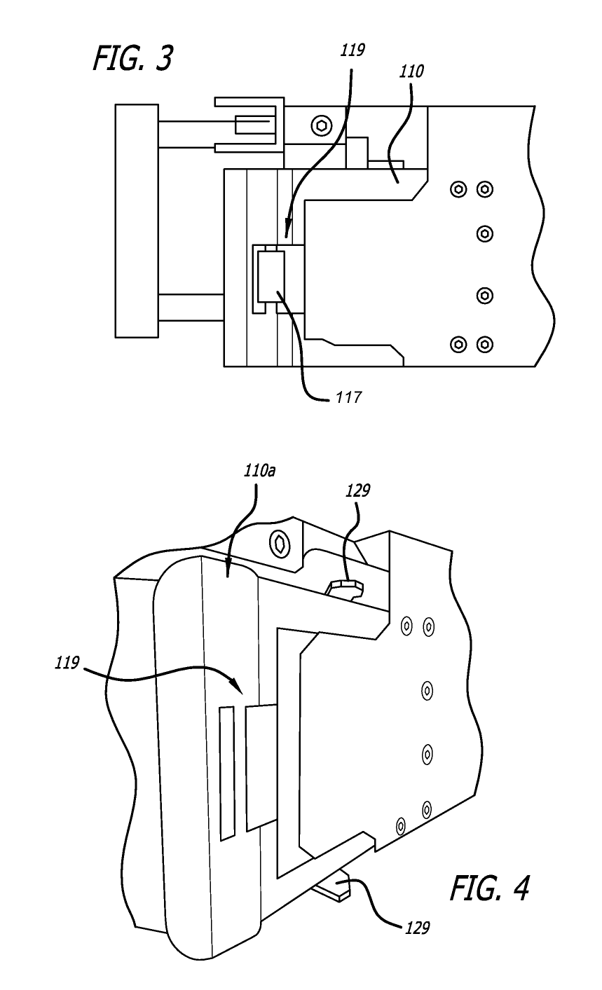

A first spring loaded side lock 118 may be integrally connected to and extend outwardly from the first side rail 108 of the tray assembly 100 (See FIG. 2) and a second spring loaded side lock 119 may be integrally connected to and extend outwardly from the second side rail 110 of the tray assembly 100 (See FIG. 3).

A first slide rail 114 may be mounted to the first side rail 108 and a second slide rail 115 may be mounted to the second side rail 110. The first and second side rails 114, 115 may be adapted to receive the enclosure 112 such that the enclosure may be slid into, out of, or retained within the tray assembly 100. FIG. 2 illustrates the enclosure 112 in the second position where the enclosure is received within the first slide rail 114 and the second slide rail 115 of the tray assembly 100 and the enclosure is slid partially outwards for maintenance, repair, etc. while the enclosure is still powered and running.

Retaining clips 116, 117 may be used to retain the enclosure 112 within the tray assembly 100. The retaining clips 116, 117, located on opposite sides of the enclosure 112, are adapted to be received within, or clip onto, the first and second inward spring loaded side locks 118, 119 of the tray assembly 100, respectively, maintaining the enclosure 112 within the tray assembly 100 in a first position. When in a first position, the enclosure 112 is fully contained within the tray assembly 100. When in a second position, the enclosure 112 is partially slid outward from the tray assembly 100 allowing access for service. FIG. 3 illustrates the second side lock 119 compressed and retained by the retaining clip 117. FIG. 4 illustrates the second side lock 119 released and sprung out from the retaining clip 117.

As described previously, when within the tray assembly 100, the enclosure 112 may be located within a first position, a second position or a third position. When in the first position, the enclosure 112 is fully received within the tray assembly and the tray assembly 100 is fully received within the rack and is operational (i.e. powered On and functional). When in the second position, the tray assembly 100 is fully received within the rack and the enclosure 112 is partially slid out of the tray assembly 100 and rack for maintenance, repair, etc. while the enclosure 112 is still powered and running. When in the third position, the enclosure 112 is fully received within the tray assembly 100 and the tray assembly 100 and enclosure 112. That is, the tray assembly 100 and enclosure 112 are locked together allowing for easy insertion into or removal from the rack.

As shown in FIG. 1, the tray assembly 100 may include a bus bar connector 120, power cables 122 and power cable management system 124. The power cable management system 124 may include a first arm member 124a and a second arm member 124b pivotally connected to a center arm member 124c. The first arm member 124a, the second arm member 124b and the center arm member 124c may be U-shaped channels adapted to receive the power cables 122. Although U-shaped channels are shown and described, this is by way of example only and other shaped members known in the art may be utilized.

According to one embodiment, the power cables 122 may be secured within the first arm member 124a, the second arm member 124b and the center arm member by fastening means 136 wrapped around the arm members 124a, 124b. A first end of the power cables may be secured to a power connector on the back end of the enclosure 112 and a second end of the power cables may be secured to the bus bar connector 120 located on the back rail 104 of the tray assembly 100.

As the enclosure 112, located within the tray assembly 100 and connected to the power cable 122, is within the tray assembly 100, the power cable management system 124 is adapted to move between a first position and a second position. When in a first position, the first arm member 124a and the second member 124b are substantially parallel to each other and located at the back end of the tray assembly 100. When in a second position, the second arm member 124b extends outward such that the power cable management system 124 has a generally triangular configuration when in a fully extended position (as shown in FIG. 1). The power cable management system 124 moves between the first position and the second position when the enclosure 112 is being slid into or out (at least partially) of the tray assembly 100.

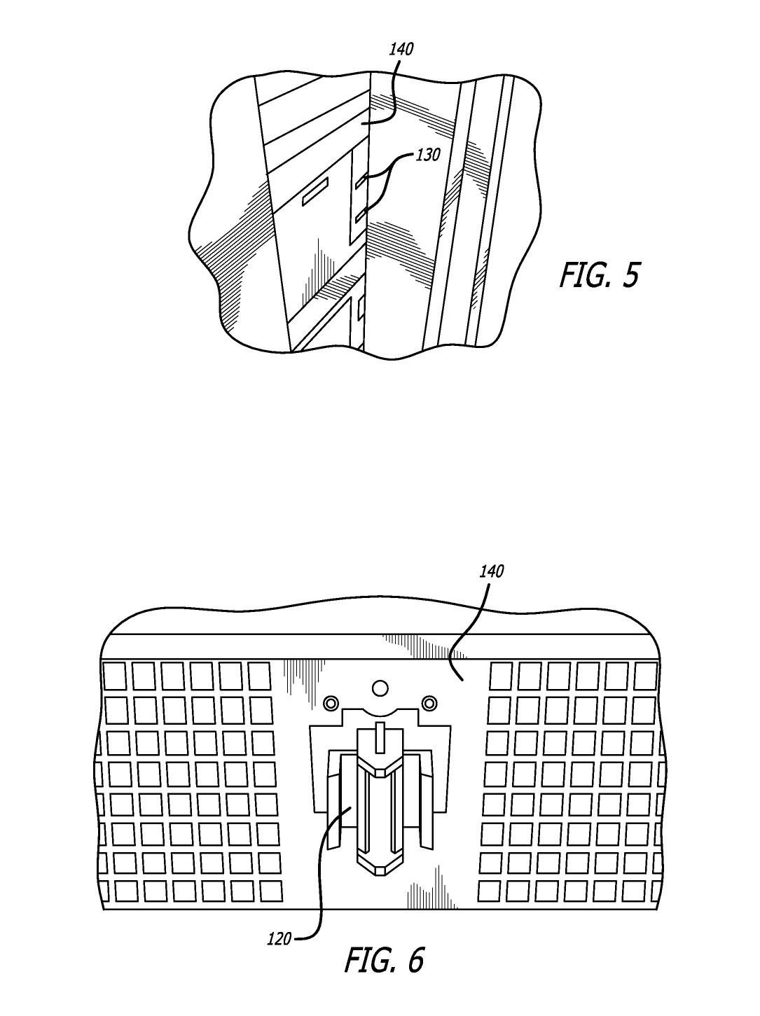

According to one embodiment, the first spring loaded side lock 118 may include a first pair of hooks 128 (See FIG. 2) and the second spring loaded side lock 119 may include a second pair of hooks 129 (See FIGS. 3-4). The first pair of hooks 128 may be integrally connected to and extend perpendicularly outward from the first spring loaded side lock 118 while the second pair of hooks 129 may be integrally connected to and extend perpendicularly outward from the second spring loaded side lock 119. The first and second pair of hooks 128 and 129 may be adapted to be received within holes or cutouts 130 on the rack 140 into which the tray assembly is inserted or placed. (See FIG. 5) When the tray assembly 100 is slid into the rack 140, the first and second pair of hooks 128 and 129 may automatically engage with and latch into the holes 130.

Additionally, when the tray assembly 100 is slid into the rack 140, the bus bar connector 120 extending outwardly from the back rail 104 (See FIG. 6) may be automatically connected to the power supplied through the rack 140.

### Installation

First, the enclosure 112 may be slid into the first and second side rails 114 and 115 of the tray assembly 100. Continuing to slide the enclosure 112 into the tray assembly 100 causes the first retaining clip 116 to automatically clip or latch onto the first inward spring loaded side lock 118 and the second retaining clip 117 to automatically clip or latch onto the second inward spring loaded side lock 119 retaining the enclosure 112 within the tray assembly 100. FIG. 8 illustrates the tray assembly 100 and enclosure 112 installed in a rack.

Next, the combined tray assembly 100 and enclosure 112 is placed on supporting “L” brackets (or any other type of bracket known in the art) located within the rack 140 and pushed into the rack 140 until the bus bar connector 120 mates and the tray assembly 100 encounter stops in the rack 140. When inserted fully into the rack 140, the first pair of hooks 128 on the first spring loaded side lock 118 and the second pair of hooks 129 on the second inward spring loaded side lock 119 automatically engage with and latch into the holes 130 on the rack 140. (See FIG. 5)

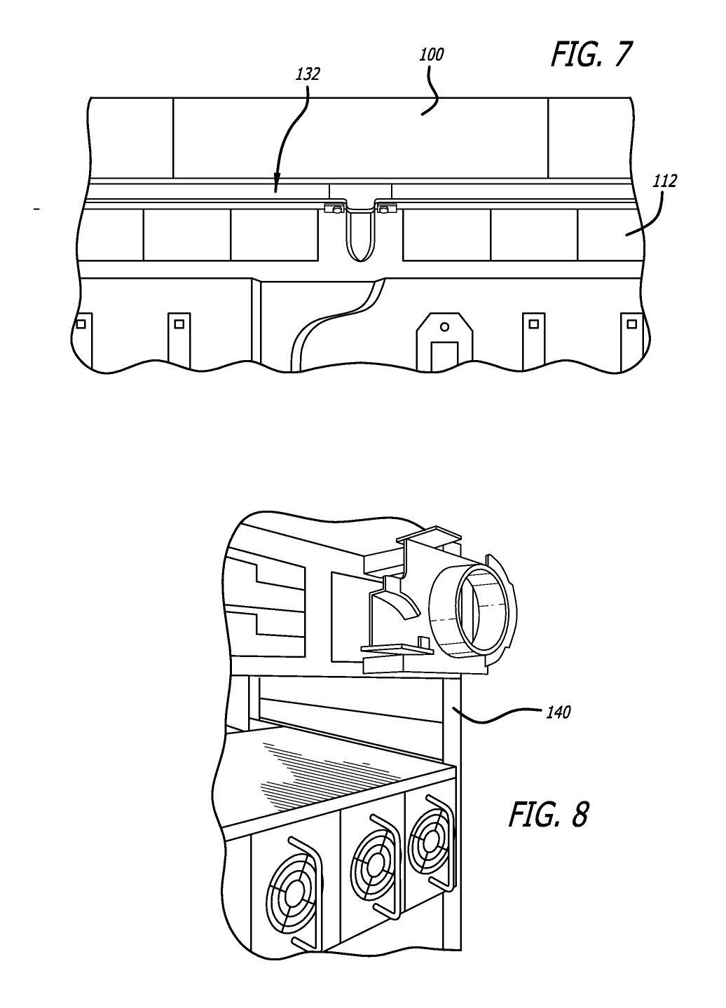

A small gap 132 exists between the rear of the enclosure 112 and its stop in the tray assembly 100. (See FIG. 7) Continuing to push the tray assembly 100 into the rack closes this gap.

While the combined enclosure 112 and tray assembly 100 are located within the rack, the enclosure may be partially slid out of the tray assembly 100 for maintenance, repair, etc. of the enclosure 112. By only partially sliding the enclosure 112 out of the tray assembly 100 while the tray assembly 100 is in the rack, the enclosure 112 can undergo maintenance and/or repair while the enclosure is still powered and running. As described previously, the first pair of hooks 128 on the first spring loaded side lock 118 and the second pair of hooks 129 on the second inward spring loaded side lock 119 automatically engage with and latch into the holes 130 on the rack 140. As the enclosure 112 is secured to the first and second slide rails 114 and 115 of the tray assembly 100, the enclosure may be partially slid out from the tray enclosure 100 while the tray enclosure 100 is secured within the rack 140.

To remove the combined enclosure 112 and tray assembly 100, the first and second inward spring loaded side locks 118 and 119 may be pressed or squeezed inwardly causing the first and second inward spring loaded side locks 118 and 119 to be released from the first and second retaining clips 116 and 117, respectively. The combined enclosure 112 and tray assembly 100 may then be slid out of the rack 140.

Those of skill in the art would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art.

1. A tray assembly for a rack mount storage unit, comprising:
a back rail;
a pair of side rails, the back rail located between and integrally connected to the pair of side rails;
a pair of slide rails mounted to the pair of side rails and adapted to receive an enclosure, the pair of slide rails allowing the enclosure to be slid into and partially out of the tray assembly;
a pair of inward spring loaded side locks integrally connected to and extending outwardly from the pair of side rails;
a bus bar connector located in the back rail; and
a power cable management system, operable between a first position and a second position, located in an interior space of the housing and adapted for receiving power cables, wherein a first end of the power cable management system is pivotably secured to the back rail and a second end of the power cable management system moves within the interior space of the housing in direct relation to the movement of the enclosure.

2. The tray assembly of claim 1, wherein the power cable management system comprises:
a first arm member;
a second arm member; and
a center arm member, the center arm member pivotably secured between the first arm member and the second arm member.

3. The tray assembly of claim 2, wherein the second arm member is U-shaped and adapted to receive the power cables.

4. The tray assembly of claim 2, wherein the center arm member is U-shaped and adapted to receive the power cables.

5. The tray assembly of claim 1, further comprising a pair of hooks extending perpendicularly outward from the pair of inward spring loaded side locks adapted to be received within holes in the rack mount storage unit.

6. The tray assembly of claim 1, wherein when the power cable management system is in the first position, the first arm member and second arm member are located substantially parallel to each other.

7. The tray assembly of claim 1, wherein when the power cable management system is in the second position, the first arm member and the second arm member have a generally triangular configuration.

8. The tray assembly of claim 1, wherein the power cable management system moves between the first position and the second position when the enclosure is being slid into or at least partially out of the tray assembly.

9. The tray assembly of claim 1, wherein the pair of slide rails allows the enclosure to slide partially outwards from the tray assembly when the tray assembly is installed in the rack mount storage unit.

10. The tray assembly of claim 1, wherein the enclosure includes a pair of retaining clips located on opposite sides of the enclosure and adapted to clip onto the pair of inward spring loaded side locks securing the enclosure entirely within the tray assembly.

11. The tray assembly of claim 1, wherein a first end of the power cables is secured to a power connector located on a back end of the enclosure.

12. The tray assembly of claim 11, wherein a second end of the power cables is secured to the bus bar connector located on the back rail of the tray assembly.

13. A tray assembly for a rack mount storage unit, comprising:
a back rail;
a pair of side rails, the back rail located between and integrally connected to the pair of side rails;
a pair of slide rails mounted to the pair of side rails and adapted to receive an enclosure, the pair of slide rails allowing the enclosure to be slid into and partially out of the tray assembly;
a pair of inward spring loaded side locks integrally connected to and extending outwardly from the pair of side rails;
a bus bar connector located in the back rail; and
a power cable management system, operable between a first position and a second position, located in an interior space of the housing and adapted for receiving power cables, wherein a first end of the power cable management system is pivotably secured to the back rail and a second end of the power cable management system moves within the interior space of the housing in direct relation to the movement of the enclosure;
wherein the power cable management system moves between the first position and the second position when the enclosure is being slid into or at least partially out of the tray assembly.

14. The tray assembly of claim 13, wherein the power cable management system comprises:
a first arm member;
a second arm member having a U-shape and adapted to receive the power cables; and
a center arm member having a U-shape and adapted to receive the power cables, the center arm member pivotably secured between the first arm member and the second arm member.

15. The tray assembly of claim 13, further comprising a pair of hooks extending perpendicularly outward from the pair of inward spring loaded side locks adapted to be received within holes in the rack mount storage unit.

16. The tray assembly of claim 13, wherein when the power cable management system is in the first position, the first arm member and second arm member are located substantially parallel to each other.

17. The tray assembly of claim 13, wherein when the power cable management system is in the second position, the first arm member and the second arm member have a generally triangular configuration.

18. The tray assembly of claim 13, wherein the power cable management system moves between the first position and the second position when the enclosure is being slid into or at least partially out of the tray assembly.

19. The tray assembly of claim 13, wherein the pair of slide rails allows the enclosure to slide partially outwards from the tray assembly when the tray assembly is installed in the rack mount storage unit.

20. The tray assembly of claim 13, wherein the enclosure includes a pair of retaining clips located on opposite sides of the enclosure and adapted to clip onto the pair of inward spring loaded side locks securing the enclosure entirely within the tray assembly.
